(19) United States
(12) Patent Application Publication
(10) Pub. No.: US 2025/0096529 A1
(43) Pub. Date: Mar. 20, 2025

(54) SURFACE EMITTING LASER, LASER DEVICE, DETECTION DEVICE, MOBILE OBJECT, AND SURFACE EMITTING LASER DRIVING METHOD

(71) Applicants: Naoto JIKUTANI, Miyagi (JP); Kazuhiro HARASAKA, Miyagi (JP)

(72) Inventors: Naoto JIKUTANI, Miyagi (JP); Kazuhiro HARASAKA, Miyagi (JP)

(21) Appl. No.: 18/292,966

(22) PCT Filed: Jun. 29, 2022
(86) PCT No.: PCT/IB2022/056039

§ 371 Date: Jan. 29, 2024

(30) Foreign Application Priority Data
Jul. 30, 2021 (JP) 2021-126012

(51) Int. Cl. H01S 5/062; G01S 7/481; H01S 5/183

(52) U.S. Cl. CPC H01S 5/062; G01S 7/4814; H01S 5/18361

(57) ABSTRACT

A surface emitting laser includes: an active layer; multiple reflectors with the active layer therebetween; a multi-quantum well structure including multiple semiconductor layers; a first electrode pair connected to a first power supply device to inject a current into the active layer; and a second electrode pair connected to a second power supply device to apply an electric field to the multiple-quantum well structure. The surface emitting laser has: a current injection period; a current decrease period after the current injection period; an electric-field application period to apply an electric field to the multi-quantum well structure; and an electric-field decrease period after the electric-field application period. At least part of the current injection period is included in a part of the electric-field application period. The surface emitting laser does not oscillate a laser beam during the electric-field application period and oscillates a laser beam during the electric-field decrease period.

### TECHNICAL FIELD

The present disclosure relates to a surface emitting laser, a laser device, a detection device, a mobile object, and a surface emitting laser driving method.

### BACKGROUND ART

The safety standards for lasers against human eyes are classified in accordance with the classes of eye-safe, and are determined in IEC 60825-1 Ed. 3 (corresponding to Japanese Industrial Standard (JIS) C 6802). To use a distance measurement device in various environments, it is desirable to satisfy the standards of Class 1 in which a safety measure or a warning is not required. The upper limit of the average power is determined as one of the standards of Class 1. In the case of pulsed light, the peak output, the pulse width, and the duty ratio of the pulsed light are converted into the average power and the average power is compared with standard values. Since the allowable peak output increases as the pulse width of the optical pulse decreases, a laser beam source with a high peak output and a short pulse width is useful for both an increase in precision and an increase in distance in a time of flight (TOF) sensor while satisfying eye-safe.

Measures for reducing the width of a pulse to 1 ns or less include gain switching, Q-switching, and mode-locking. The gain switching is a measure for providing a pulse width of 100 ps or less by using a relaxation oscillation phenomenon. Merely controlling the pulse current can provide such a pulse width, and hence the configuration for the guide switching is simpler than that for the Q-switching or mode-locking.

However, since the gain switching uses the relaxation oscillation phenomenon, multiple pulse trains are likely to be output after the leading pulse. In another situation, tail light (tailing) with a wide pulse width is likely to be output after the relaxation oscillation has subsided. These phenomena are not desirable for application. For example, when a single photon avalanche diode (SPAD) is used to perform detection of the Geiger mode, the highest peak output is the target of sensing, and multiple pulses other than the target pulse result in noise. Moreover, tail light is unnecessary energy, which is disadvantageous in terms of eye-safe.

### CITATION LIST

### Patent Literature

### [PTL 1]

U.S. Pat. No. 8,934,514-B

### [NPL 1]

H. Yamamoto, M. Asada and Y. Suematsu, “Electric-field-induced refractive index variation in quantum-well structure”, Electron. Lett., 21 p.p. 579-580 (1985). [NPL 2]
H. Nagai, M. Yamanishi, Y. Kan and I. Suemune, “Field-induced modulation of refractive index and absorption coefficient in a GaAs/AlGaAs quantum well structure”, Elect. Lett., 22 p.p. 888-889 (1986).

### [NPL 3]

H. Nagai, M. Yamanishi, Y. Kan, I. Suemune, Y. Ide and R. Lang, “Excitation-induced dispersion of electroreflectance in a GaAs/AlAs quantum well structure at room temperature”, Extended abstract of the 18th conference on Solid State Devices and Materials, p. p. 591-594 (1986).

### [NPL 4]

J. S. Weiner, D. A. B. Miller and D. S. Chemla, “Quadratic electro-optics effect due to the quantum confined Stark effect in quantum wells”, Appl. Phys. Lett., 50, 13, p.p. 842-844 (1987).

### SUMMARY OF INVENTION

### Technical Problem

There is room for study on a surface emitting laser capable of generating short-pulse light with reduced tailing.

An object of the present disclosure is to provide a surface emitting laser, a laser device, a detection device, a mobile object, and a surface emitting laser driving method capable of obtaining short-pulse light with reduced tailing.

### Solution to Problem

According to an aspect of the disclosed technology, a surface emitting laser includes: an active layer; multiple reflectors facing each other with the active layer therebetween; a multi-quantum well structure including multiple semiconductor layers in an optical path of a laser beam emitted from the active layer and the multiple reflectors; a first electrode pair connected to a first power supply device and configured to inject a current into the active layer; and a second electrode pair connected to a second power supply device and configured to apply an electric field to the multi-quantum well structure in a direction perpendicular to a well surface of the multiple-quantum well structure. The surface emitting laser has: a current injection period in which the first power supply device injects the current into the active layer; a current decrease period after the current injection period, in which the current injected into the active layer is lower than the current injected during the current injection period; an electric-field application period in which the second power supply device applies an electric field to the multi-quantum well structure; and an electric-field decrease period after the electric-field application period, in which the electric field applied to the multi-quantum well structure is larger than the electric field applied during the electric-field application period. At least part of the current injection period is included in at least part of the electric-field application period. The surface emitting laser does not oscillate a laser beam during the electric-field application period, and oscillates a laser beam during the electric-field decrease period. According to another aspect of the disclosed technology, a laser device including the surface emitting laser; a first power supply device connected to the first electrode pair; and a second power supply device connected to the second electrode pair.

According to still another aspect of the disclosed technology, a detection device includes: the above-described laser device; and a detector configured to detect light emitted from the surface emitting laser and reflected by an object.

According to yet another aspect of the disclosed technology, a mobile object includes the above-described detection device.

Further, a surface emitting laser driving method, performed by a surface emitting laser including an active layer, multiple reflectors facing each other with the active layer therebetween, a multi-quantum well structure including multiple semiconductor layers in an optical path of a laser beam emitted from the active layer and the multiple reflectors, a first electrode pair connected to a first power supply device and configured to inject a current into the active layer; and a second electrode pair connected to a second power supply device and configured to apply an electric field to the multi-quantum well structure in a direction perpendicular to a well surface of the multiple-quantum well structure, the method including: not oscillating a laser beam during an electric-field application period; and oscillating a laser beam during an electric-field decrease period. The electric-field application period is a period in which the second power supply device applies an electric field to the multiple-quantum well structure, the electric-field decrease period is a period after the electric-field application period, in which the electric field applied to the multi-quantum well structure is larger than the electric field applied during the electric-field application period, and at least part of a current injection period is included in at least part of the electric-field application period. The current injection period is a period in which the first power supply device injects the current into the active layer; and a current decrease period is a period after the current injection period, in which the current injected into the active layer is lower than the current injected during the current injection period.

### Advantageous Effects of Invention

With the disclosed technology, short-pulse light with reduced tailing can be obtained.

### BRIEF DESCRIPTION OF DRAWINGS

The accompanying drawings are intended to depict example embodiments of the present invention and should not be interpreted to limit the scope thereof. The accompanying drawings are not to be considered as drawn to scale unless explicitly noted. Also, identical or similar reference numerals designate identical or similar components throughout the several views.

FIG. 1 is a cross-sectional view of a surface emitting laser 100 according to a first example.

FIG. 2 is a cross-sectional view of an oxidized confinement layer and the vicinity thereof according to the first example.

FIG. 3 is a cross-sectional view of an oxidized confinement layer and the vicinity thereof according to a second example.

FIG. 4 is an equivalent circuit diagram of a circuit used for actual measurement.

FIG. 5A is a graph presenting an actual measurement result of the second example.

FIG. 5B is a graph presenting an actual measurement result of the second example.

FIG. 5C is a graph presenting an actual measurement result of the second example.

FIG. 6A is a graph presenting an actual measurement result of the first example.

FIG. 6B is a graph presenting an actual measurement result of the first example.

FIG. 6C is a graph presenting an actual measurement result of the first example.

FIG. 7A is a graph presenting a difference in distributions of electric field intensity and equivalent refractive index depending on a structure.

FIG. 7B is a graph presenting a difference in distributions of electric field intensity and equivalent refractive index depending on a structure.

FIG. 8A is a graph presenting a change in distributions of electric field intensity and equivalent refractive index over time.

FIG. 8B is a graph presenting a change in distributions of electric field intensity and equivalent refractive index over time.

FIG. 9 is a graph presenting simulation results for carrier density and threshold carrier density according to the second example.

FIG. 10 is a graph presenting simulation results for optical output according to the second example.

FIG. 11 is a graph presenting the first example of a function used in a simulation according to the first example.

FIG. 12 is a graph presenting simulation results for optical output according to the first example.

FIG. 13A is a graph presenting simulation results for carrier density, threshold carrier density, and photon density according to the first example.

FIG. 13B is a graph presenting a simulation result for optical confinement factor in a lateral direction according to the first example.

FIG. 14A is a partially enlarged graph of FIG. 13A.

FIG. 14B is a partially enlarged graph of FIG. 13B.

FIG. 15A is a graph presenting the first example of an actual measurement result of optical pulses.

FIG. 15B is a graph presenting the first example of a simulation result of optical pulses.

FIG. 16 is a graph presenting the relation between the current confinement area and the peak optical output.

FIG. 17 is a cross-sectional view of a surface emitting laser according to a first embodiment.

FIG. 18A is a cross-sectional view of a surface emitting laser according to a second embodiment.

FIG. 18B is a top view of the surface emitting laser in FIG. 18A.

FIG. 19 is a cross-sectional view of a surface emitting laser according to a third embodiment.

FIG. 20 is a cross-sectional view of a surface emitting laser according to a fourth embodiment.

FIG. 21 is a cross-sectional view of a surface emitting laser according to a fifth embodiment.

FIG. 22 is a cross-sectional view of a surface emitting laser according to a sixth embodiment.

FIG. 23 is a diagram illustrating a laser device according to a seventh embodiment.

FIG. 24 is a graph presenting the relation between the duty ratio and the peak output of optical pulses.

FIG. 25 is a diagram illustrating a distance measurement device according to an eighth embodiment.

FIG. 26 is a diagram of a mobile object according to a ninth embodiment.

### DESCRIPTION OF EMBODIMENTS

The terminology used herein is for the purpose of describing particular embodiments only and is not intended to be limiting of the present invention. As used herein, the singular forms “a”, “an” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Embodiments of the present disclosure are described below with reference to the accompanying drawings. In the specification and the drawings, components having substantially the same functional configuration are denoted by the same reference sign, and redundant description may be omitted.

Firstly, the gist of the present disclosure is described below with reference to control samples. In the specification and the drawings, components having substantially the same functional configuration are denoted by the same reference sign, and redundant description may be omitted.

### First Reference Example

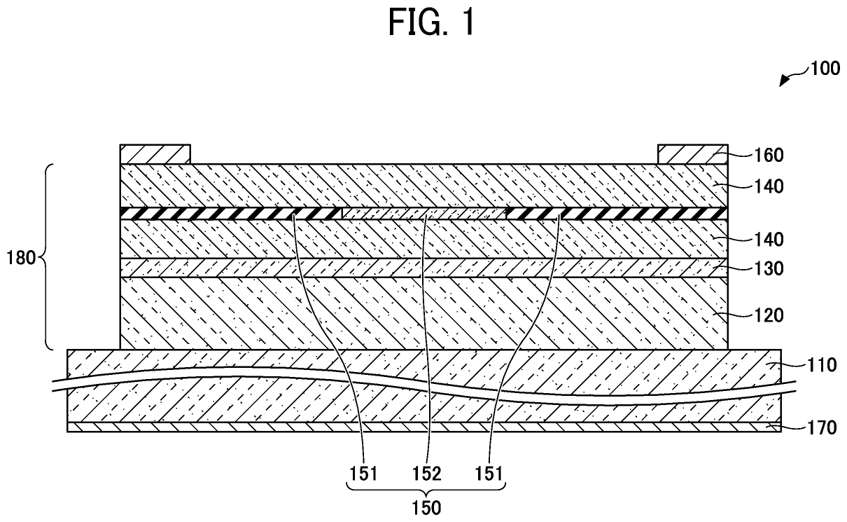

A first reference example is described. The first example relates to a surface emitting laser. FIG. 1 is a cross-sectional view illustrating a surface emitting laser 100 according to the first example.

The surface emitting laser 100 according to the first example is, for example, a vertical cavity surface emitting laser (VCSEL) using oxidation confinement. The surface emitting laser 100 includes an n-type GaAs substrate 110, an n-type distributed Bragg reflector (DBR) 120, an active layer 130, a p-type DBR 140, an oxidized confinement layer 150, an upper electrode 160, and a lower electrode 170.

In the first example, light is emitted in a direction perpendicular to a surface of the n-type GaAs substrate 110. Hereinafter, the direction perpendicular to the surface of the n-type GaAs substrate 110 may be referred to as a vertical direction, and the direction parallel to the surface of the n-type GaAs substrate 110 may be referred to as a lateral direction or an in-plane direction.

The n-type DBR 120 overlies the n-type GaAs substrate 110. The n-type DBR 120 is, for example, a semiconductor multilayer-film reflecting mirror including a plurality of n-type semiconductor films stacked on one another. The active layer 130 overlies the n-type DBR 120. The active layer 130 includes, for example, a plurality of quantum well layers and a plurality of barrier layers. The active layer 130 is included in the resonator. The p-type DBR 140 overlies the active layer 130. The p-DBR 147 is, for example, a semiconducting multilayer reflector composed of a plurality of p-type semiconductor films that are multilayered.

The upper electrode 160 is in contact with an upper surface of the p-type DBR 140 in plan view. The lower electrode 170 is in contact with a lower surface of the n-type GaAs substrate 110. The pair of the upper electrode 160 and the lower electrode 170 is an example of an electrode pair. However, the positions of the electrodes are not limited thereto, and may be any positions as far as the electrodes can inject current into the active layer. For example, an intracavity structure may be employed in which electrodes are directly disposed in a spacer layer of a resonator instead of via a DBR.

The p-type DBR 140 includes, for example, the oxidized confinement layer 150. The oxidized confinement layer 150 contains Al. The oxidized confinement layer 150 includes an oxidized region 151 and a non-oxidized region 152 in a plane perpendicular to the direction in which light is emitted (hereinafter, referred to as an emission direction of light). The oxidized region 151 has an annular planar shape and surrounds the non-oxidized region 152. The non-oxidized region 152 includes a p-type AlAs layer 155 and two p-type Al_{0.85}Ga_{0.15}As layers 156 that sandwich the p-type AlAs layer 155 in the vertical direction. The oxidized region 151 is made of AlOx. The refractive index of the oxidized region 151 is lower than the refractive index of the non-oxidized region 152. For example, the refractive index of the oxidized region 151 is 1.65, the refractive index of the p-type AlAs layer 155 is 2.96, and the refractive index of the p-type Al_{0.85}Ga_{0.15}As layers 156 is 3.04. In plan view, a portion of a mesa 180 inside an inner edge of the oxidized region 151 is an example of a high refractive index region, and a portion of the mesa 180 outside the inner edge of the oxidized region 151 is an example of a low refractive index region. In one example, p-type AlxGa₁₋ₓAs layers (0.70≤x≤0.90) may be provided instead of the p-type Al_{0.85}Ga_{0.15}As layers 156. In the present embodiment, the p-type DBR 140, the active layer 130, and the n-type DBR 120 constitute the mesa 180. However, in the present embodiment in which a current confinement region is formed by oxidation confinement, at least the oxidized confinement layer 150 and a semiconductor layer located above the oxidized confinement layer 150 are formed in a mesa shape. When at least the active layer is formed to be included in the mesa, light generated in the active layer can be prevented from leaking in the lateral direction.

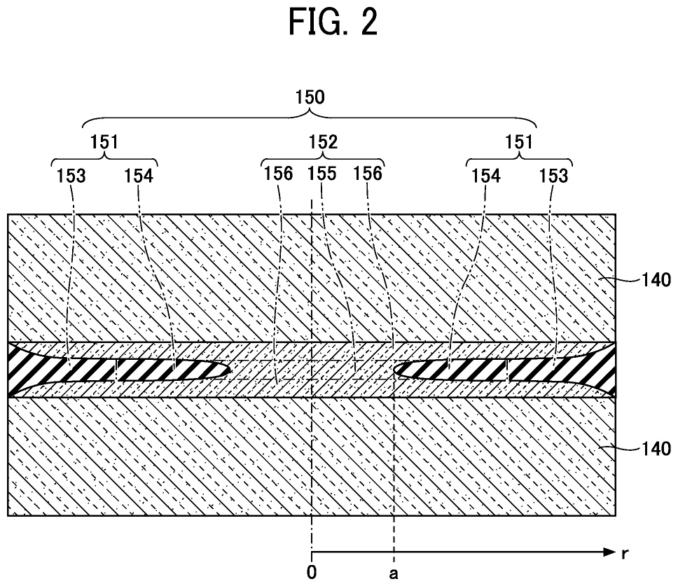

The oxidized confinement layer 150 is described in detail. FIG. 2 is a cross-sectional view illustrating an oxidized confinement layer and the vicinity thereof according to the first example.

As illustrated in FIG. 2, the oxidized region 151 has, in plan view, an annular outer region 153 and an annular inner region 154. The outer region 153 is exposed from a side surface of the mesa 180. The outer region 153 is a region in which the thickness changes so that the contact surface of the surface is located in an outer section of the oxidized region 151 in cross-sectional view. The inner region 154 is a region in which the thickness changes so that the contact surface of the surface is located in an inner section of the oxidized region 151 in cross-sectional view. The inner region 154 is located inside the outer region 153. The thickness of the inner region 154 matches the thickness of the outer region 153 at the boundary with the outer region 153, and decreases toward the center of the mesa 180. The inner region 154 has a tapered shape that is gradually thicker from the inner edge to the boundary with the outer region 153 in cross-sectional view. The non-oxidized region 152 is located inside the outer region 153. Portions of the non-oxidized region 152 sandwich the inner region 154 in the vertical direction. The other portion of the non-oxidized region 152 is located inside the inner edge of the inner region 154 in plan view. For example, the thickness of the non-oxidized region 152 is 35 nm or less. The thickness of the outer region 153 may be larger than the thickness of the non-oxidized region 152. In the embodiment of the present disclosure, the thickness of the non-oxidized region 152 is the thickness of a portion on the center side of the mesa 180 with respect to the inner edge of the oxidized region 151 (the inner edge of the inner region 154). For example, the distance from the side surface of the mesa 180 to the inner edge of the oxidized region 151 is in a range from about 8 μm to about 11 μm.

The oxidized region 151 is formed by, for example, oxidation confinement of a p-type AlAs layer and a p-type Al_{0.85}Ga_{0.15}As layer. For example, the oxidized region 151 can be formed by oxidizing the p-type AlAs layer and the p-type Al_{0.85}Ga_{0.15}As layer in a high-temperature water vapor environment. Even when the same p-type AlAs layer and the same p-type Al_{0.85}Ga_{0.15}As layer are oxidized, the structure of the oxidized confinement layer obtained from the p-type AlAs layer and the p-type Al_{0.85}Ga_{0.15}As layer may vary depending on the conditions of oxidation. Thus, even when the layers to be the oxidized confinement layer 150 by oxidation, for example, the p-type AlAs layer and the p-type Al_{0.85}Ga_{0.15}As layer have the same structures as those before oxidation, the oxidized confinement layer 150 including the oxidized region 151 and the non-oxidized region 152 is not obtained in some cases depending on the conditions of oxidation.

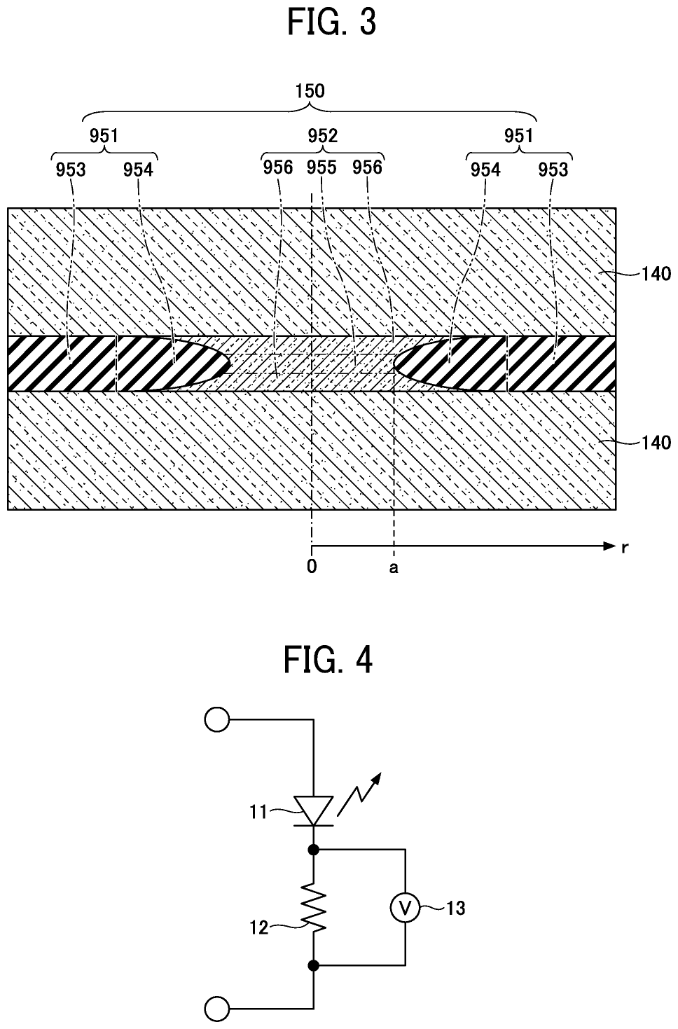

The advantageous effect of the first example is described in comparison with the second example. FIG. 3 is a cross-sectional view of an oxidized confinement layer and the vicinity thereof according to the second example.

In the second example, the oxidized confinement layer 150 includes an oxidized region 951 and a non-oxidized region 952 instead of the oxidized region 151 and the non-oxidized region 152. The oxidized region 951 has an annular planar shape and surrounds the non-oxidized region 952. The non-oxidized region 952 includes a p-type AlAs layer 955 and two p-type Al_{0.85}Ga_{0.15}As layers 956 that sandwich the p-type AlAs layer 955 in the vertical direction. The oxidized region 951 has, in plan view, an annular outer region 953 and an annular inner region 954. The outer region 953 is exposed from a side surface of a mesa 180. The thickness of the outer region 953 is constant in the in-plane direction. The inner region 954 is located inside the outer region 953. The thickness of the inner region 954 matches the thickness of the outer region 953 at the boundary with the outer region 953, and decreases toward the center of the mesa 180. The inner region 954 has a tapered shape that is gradually thicker from an inner edge to the boundary with the outer region 953 in cross-sectional view. The non-oxidized region 952 is located inside the outer region 953. Portions of the non-oxidized region 952 sandwich the inner region 954 in the vertical direction. The other portion of the non-oxidized region 952 is located inside the inner edge of the inner region 954 in plan view. For example, the distance from the side surface of the mesa 180 to the inner edge of the oxidized region 951 is in a range from about 8 μm to about 11 μm. The thicknesses of the oxidized region 951 and the non-oxidized region 952 are equal to the thickness of the oxidized confinement layer 150.

Actual measurement results according to the first example and the second example are described first. FIG. 4 is an equivalent circuit diagram of a circuit used for actual measurement.

In this circuit, a resistor 12 for monitoring current is coupled in series to a surface emitting laser 11 corresponding to the first example or the second example. A voltmeter 13 is coupled in parallel to the resistor 12. Light output from the surface emitting laser 11 was received by a wide-band high-speed photodiode and converted into a voltage signal. The voltage signal was observed with an oscilloscope.

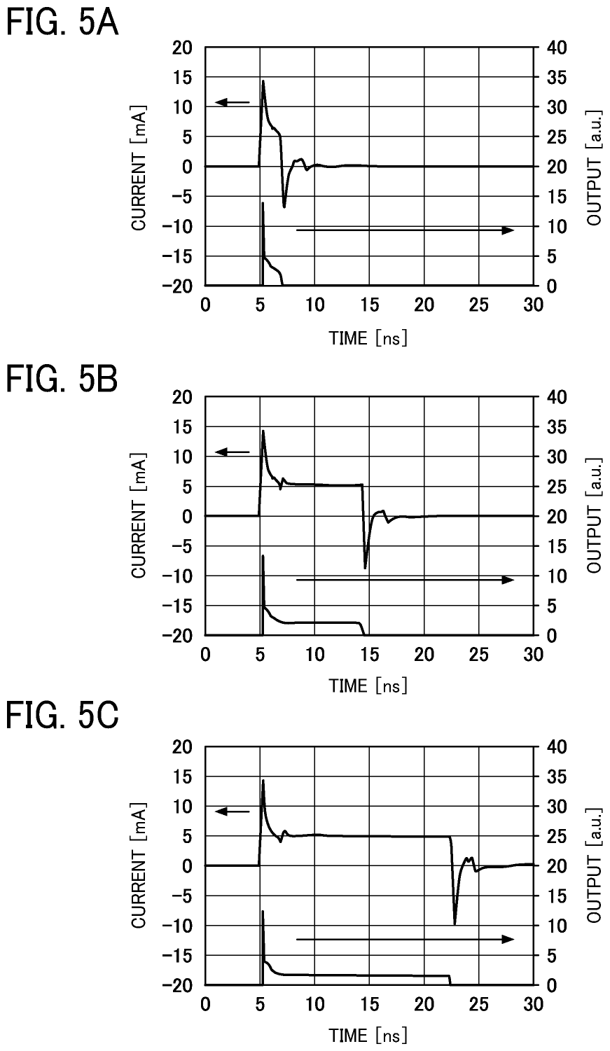

FIGS. 5A to 5C are graphs presenting actual measurement results of the second example. FIG. 5A presents an actual measurement result when the width of pulse current is about 2 ns. FIG. 5B presents an actual measurement result when the width of pulse current is about 9 ns. FIG. 5C presents an actual measurement result when the width of pulse current is about 17 ns. In the actual measurement in FIGS. 5A to 5C, the magnitude of bias current and the amplitude of pulse current are common. FIGS. 5A to 5C each present current flowing through the resistor 12 and an optical output measured by the high-speed photodiode. The current flowing through the resistor 12 can be calculated using the voltmeter 13.

As presented in FIGS. 5A to 5C, in the second example, regardless of the magnitude of the width of pulse current, an optical pulse is output immediately after the pulse current is injected, then an equilibrium state is established until the injection of the pulse current is stopped, and constant tail light is output. The leading optical pulse is caused by relaxation oscillation, which is typical driving by gain switching. Even when the pulse width is changed, the timing at which the optical pulse is generated does not change. This is because the optical pulse generated by the relaxation oscillation is generated immediately after the carrier density in the laser resonator exceeds the threshold carrier density. To reduce the output of tail light, the current injection may be stopped immediately after the optical pulse is output. However, since the time width of the optical pulse caused by the relaxation oscillation is 100 ps or less, when the magnitude of the current is as large as 10 A or more, it is difficult to stop the injection of the current in a period of 100 ps or less immediately after the optical pulse is output.

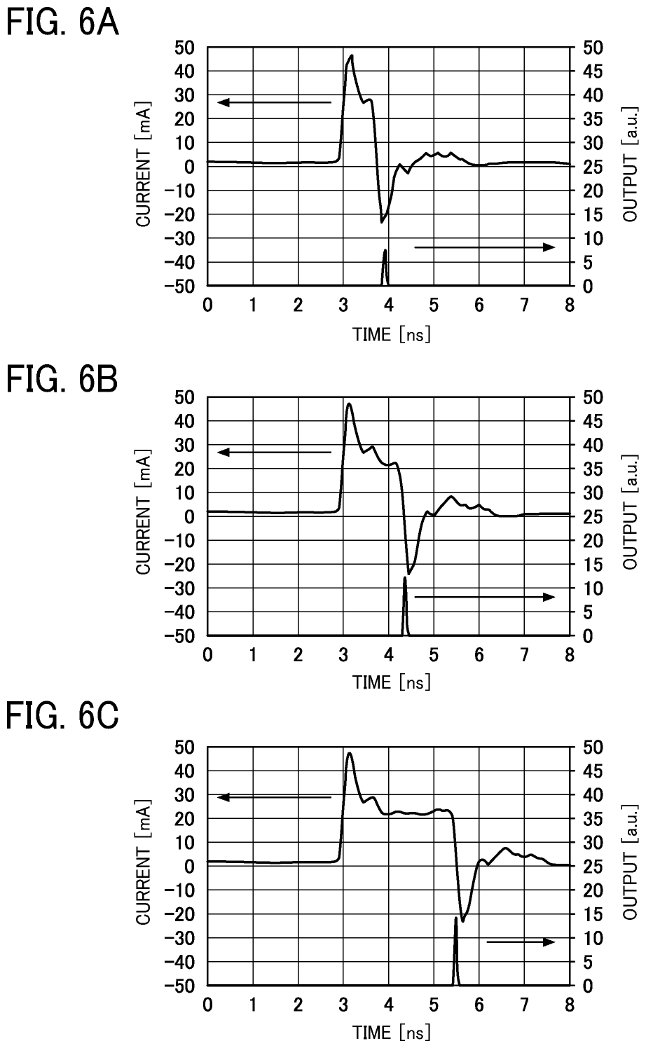

FIGS. 6A to 6C are graphs presenting actual measurement results of the first example. FIG. 6A presents an actual measurement result when the width of pulse current is about 0.8 ns. FIG. 6B presents an actual measurement result when the width of pulse current is about 1.3 ns. FIG. 6C presents an actual measurement result when the width of pulse current is about 2.5 ns. In the actual measurement in FIGS. 6A to 6C, the magnitude of bias current and the amplitude of pulse current are common. FIGS. 6A to 6C each present current flowing through the resistor 12 and an optical output measured by the high-speed photodiode. The current flowing through the resistor 12 can be calculated using the voltmeter 13.

As presented in FIGS. 6A to 6C, in the first example, an optical output is not generated in a state in which pulse current is injected, and an optical pulse is output immediately after the injection of the pulse current decreases. Moreover, tail light after the optical pulse is output is almost not observed. In the case of the optical output by gain switching, the timing at which the optical pulse is generated does not change even when the width of the pulse current is changed. In contrast, according to the first example, the optical pulse is output when the injection of the pulse current decreases. Thus, the optical output according to the first example is not based on normal gain switching using the relaxation oscillation phenomenon.

As described above, the first example and the second example clearly differ from each other in the mechanism and manner of the optical output. The difference is described as follows.

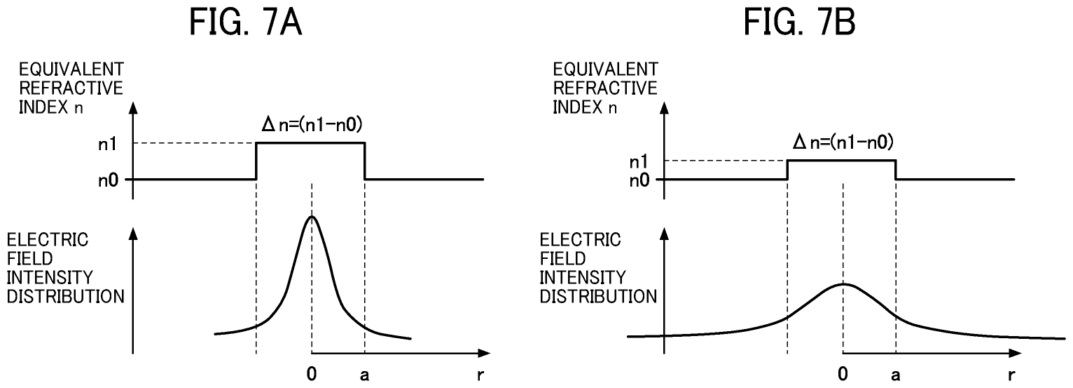

In a surface emitting laser, a laser beam propagates in a resonator in a direction perpendicular to an oxidized confinement layer. Thus, as the oxidized confinement layer is thicker, an equivalent waveguide length dependent on the difference in refractive index increases, and an optical confinement effect in the lateral direction increases. When a DBR including the oxidized confinement layer is considered as an equivalent waveguide structure, the electric field intensity distribution of laser beams is concentrated around the center when the difference in equivalent refractive index is large as presented in FIG. 7A. In contrast, when the difference in equivalent refractive index is small as presented in FIG. 7B, the electric field intensity distribution of laser beams expands to the oxidized region in the periphery. When the first example is compared with the reference second example, since the oxidized confinement layer 150 includes the inner region 154 in the first embodiment, the difference in equivalent refractive index decreases in the first example. Thus, the electric field intensity distribution of the laser beams is concentrated around the center in the second example as presented in FIG. 7A. In contrast, the electric field intensity distribution of the laser beams expands to the oxidized region 151 in the first example as presented in FIG. 7B.

In this case, an optical confinement factor in the lateral direction is defined as a ratio of “an integrated intensity of an electric field in a region having the same radius as a current passing region” to “an integrated intensity of an electric field in a lateral cross-section passing through the center of a surface emitting laser element”, and is expressed by Equation (1). In this case, a corresponds to a radius of the current passing region, and Φ represents a rotation direction around a rotation axis in the direction perpendicular to the substrate.

$$\begin{matrix}[ Equation l ] & \\ {Γ}_{r} = \frac{{\int }_{0}^{a} {\int }_{0}^{2 π} \vert E {\vert}^{2} \cdot rd Φ dr}{{\int }_{0}^{∞} {\int }_{0}^{2 π} \vert E {\vert}^{2} \cdot rd Φ dr} & ( 1 )\end{matrix}$$

A model of a phenomenon that occurs when injection of pulse current is stopped is described next. In a state in which the pulse current is injected, the current path is concentrated around the center of the mesa by the oxidized confinement layer, and the carrier density is high. At this time, an effect of decreasing the refractive index is generated by a carrier plasma effect in the non-oxidized region having a high carrier density. The carrier plasma effect is a phenomenon in which the refractive index decreases in proportion to a free carrier density. Referring to, for example, Kobayashi, Soichi, et al., “Direct Frequency Modulation in AlGaAs Semiconductor Lasers”, IEEE Transactions on Microwave Theory and Techniques, Volume 30, Issue 4, 1982, pp. 428-441, the amount of change in refractive index is expressed by Equation (2). In this case, N is a carrier density.

$$\begin{matrix}[ Equation 2 ] & \\ Δ n {=}_{.}^{.} - 4 \times 1 {0}^{- 21} [ {cm}^{3} ] \times N [ 1 / {cm}^{3} ] & ( 2 )\end{matrix}$$

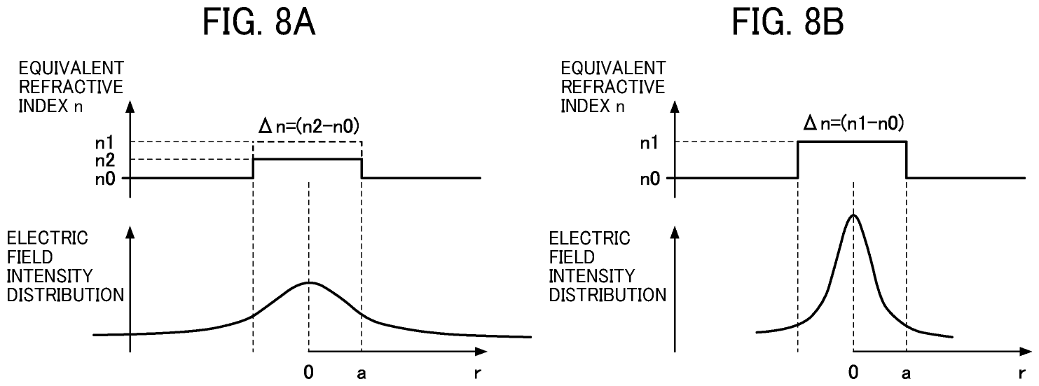

FIG. 8A schematically presents an equivalent refractive index and an electric field intensity distribution in a period in which pulse current is injected. FIG. 8B schematically presents an equivalent refractive index and an electric field intensity distribution in a period in which the injection of the pulse current is stopped and the pulse current decreases. The carrier plasma effect acts in a direction to cancel out the equivalent refractive-index difference (n1−n0) generated by the oxidized confinement layer in the period in which the pulse current is injected, and hence the equivalent refractive-index difference is (n2−n0). When the injection of the pulse current decreases in this state, the carrier plasma effect no longer acts, and the equivalent refractive-index difference returns to (n1−n0). Thus, photons that have spread to the peripheral portion of the mesa are concentrated in the center portion of the mesa, and the photon density in the non-oxidized region increases. That is, the state changes to a state in which lateral optical confinement is strong. When the injection of the pulse current is stopped, carriers accumulated in the resonator decrease over the carrier lifetime. However, when the lateral optical confinement increases before the carrier density completely attenuates, induced emission starts, the accumulated carriers are consumed at once, and an optical pulse is output. The period in which the pulse current is injected is an example of a current injection period, and the period in which the injection of the pulse current is stopped and the pulse current decreases is an example of a current decrease period.

The results of verification of the above-described model through a simulation are described below. The rate equations of the carrier density and the photon density are expressed in Equations (3) and (4).

$$\begin{matrix}[ Equation 3 ] & \\ \frac{d N}{dt} = \frac{i ( t )}{e V} - \frac{N}{{τ}_{n} ( N )} - {v}_{g} g ( N , S ) S & ( 3 )\end{matrix}$$

$$\begin{matrix}[ Equation 4 ] & \\ \frac{d S}{dt} = ( {Γ}_{a} {v}_{g} g ( N , S ) - \frac{1}{{τ}_{p}} ) S + \frac{{Γ}_{a} β N}{{τ}_{n} ( N )} & ( 4 )\end{matrix}$$

The content indicated by each character in Equations (3) and (4) is as follows:
N denotes a carrier density [1/cm³],
S denotes a photon density [1/cm³],
i(t) denotes injection current [A],
e denotes an elementary charge [C],
V denotes a resonator volume [cm³],
τₙ(N) denotes a carrier lifetime [s],
v_{g} denotes a group velocity [cm/s],
g(N, S) denotes a gain [1/cm],
Γₐ denotes an optical confinement factor,
τₚ denotes a photon lifetime [s],
β denotes a spontaneous emission coupling factor,
g₀ denotes a gain factor [1/cm],
ε denotes a gain suppression factor,
Nₜᵣ denotes a transparency carrier density [1/cm³],
ηᵢ denotes a current injection efficiency,
αₘ denotes a resonator mirror loss [1/cm],
h denotes the Planck constant [Js], and
v denotes a frequency of light [1/s].

The gain g(N, S) is expressed by Equation (5).

$$\begin{matrix}[ Equation 5 ] & \\ g ( N , S ) = \frac{{g}_{0}}{1 + ε S} ln \frac{N}{{N}_{t r}} & ( 5 )\end{matrix}$$

As expressed in Equation (6), the optical confinement factor Γₐ is defined by the product of an optical confinement factor Γᵣ in the lateral direction and an optical confinement factor Γ_{z} in the vertical direction.

$$\begin{matrix}[ Equation 6 ] & \\ {Γ}_{a} = {Γ}_{r} \times {Γ}_{z} & ( 6 )\end{matrix}$$

A threshold carrier density Nₜₕ is expressed by Equation (7).

$$\begin{matrix}[ Equation 7 ] & \\ {N}_{th} = {N}_{tr} \cdot exp ( \frac{1}{{Γ}_{a} \cdot {g}_{0} \cdot {v}_{g} \cdot {τ}_{p}} ) & ( 7 )\end{matrix}$$

A threshold current Iₜₕ and the threshold carrier density N^{th} have a relationship expressed by Equation (8).

$$\begin{matrix}[ Equation 8 ] & \\ \frac{{η}_{i} \cdot {I}_{t h}}{e \cdot V} = \frac{{N}_{t h}}{{τ}_{n} ( N )} & ( 8 )\end{matrix}$$

An optical output P that is output from the resonator and the photon density S have a relationship expressed by Equation (9).

$$\begin{matrix}[ Equation 9 ] & \\ P = {v}_{g} \cdot {α}_{m} \cdot S \cdot hv \cdot \frac{V}{{Γ}_{a}} & ( 9 )\end{matrix}$$

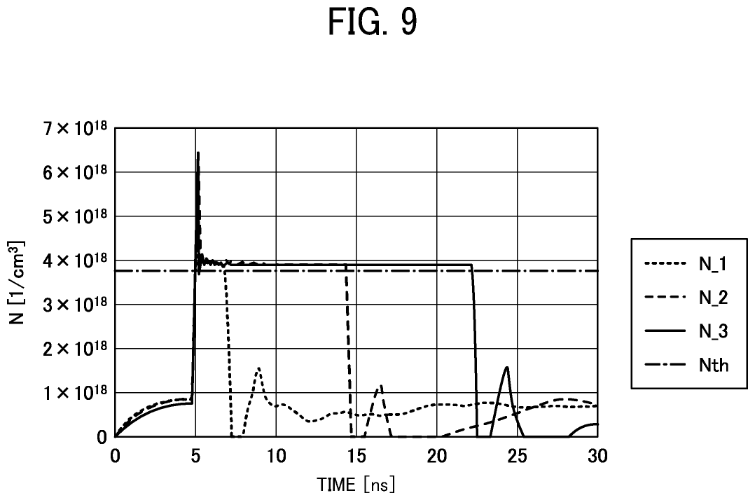

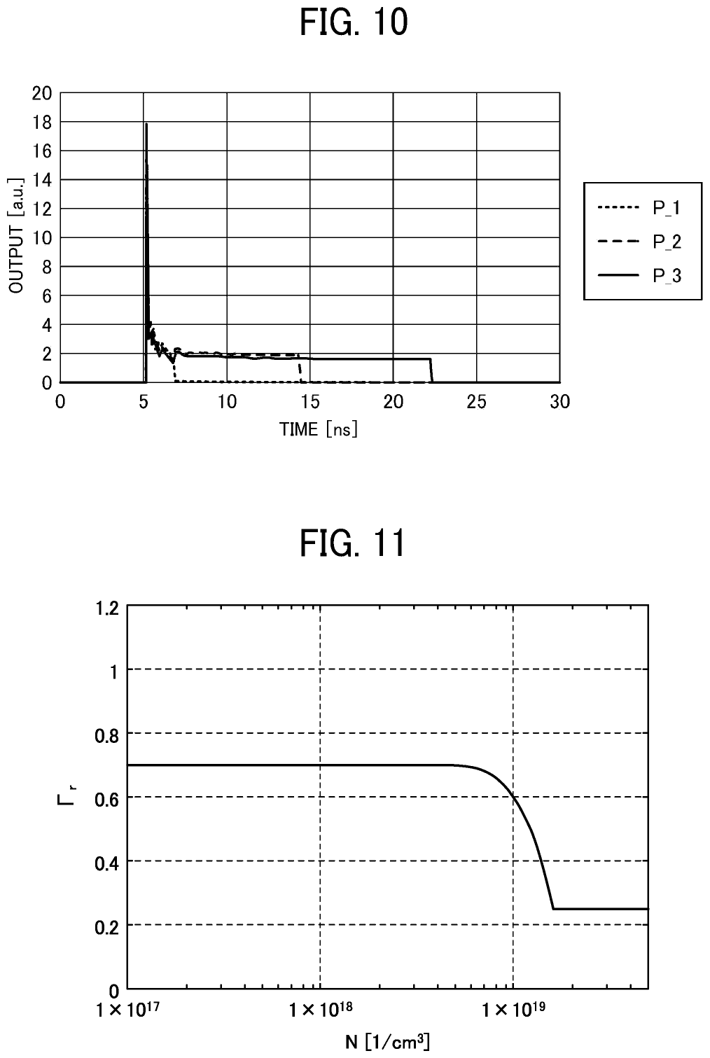

Simulation results according to the second example are described. For the second example, a simulation was performed with inputs of the current monitor waveforms presented in FIGS. 5A to 5C while the optical confinement factor Γᵣ in the lateral direction was 1. FIG. 9 presents simulation results for the carrier density N and the threshold carrier density Nₜₕ. FIG. 10 presents simulation results for the optical outputs.

As presented in FIGS. 9 and 10, at the time point of about 5 ns at which the pulse current is injected, the carrier density N exceeds the threshold carrier density Nₜₕ immediately thereafter, and an optical pulse caused by the relaxation oscillation is output. Then, an equilibrium state is established and constant tail light is output. As described above, in the simulation, results close to the actual measurement results presented in FIGS. 5A to 5C are obtained.

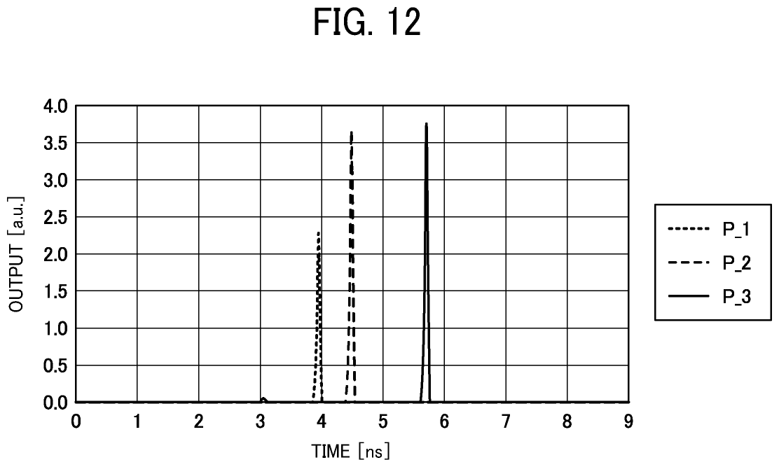

Simulation results according to the first example are described. For the first example, a simulation was performed with inputs of the current monitor waveforms presented in FIGS. 6A to 6C while the optical confinement factor Γᵣ in the lateral direction was less than 1 and the optical confinement factor Γᵣ in the lateral direction was a function that decreases as the carrier density N increases. The reason why the optical confinement factor Γᵣ in the lateral direction is the above-described function is to take in the influence of a change in refractive index due to the carrier plasma effect. FIG. 11 is a graph presenting an example of the function. FIG. 12 is a graph presenting simulation results for the optical outputs.

As presented in FIG. 12, an optical pulse output is obtained at a timing at which the injection of the pulse current is stopped. As described above, in the simulation, results close to the actual measurement results presented in FIGS. 6A to 6C are obtained.

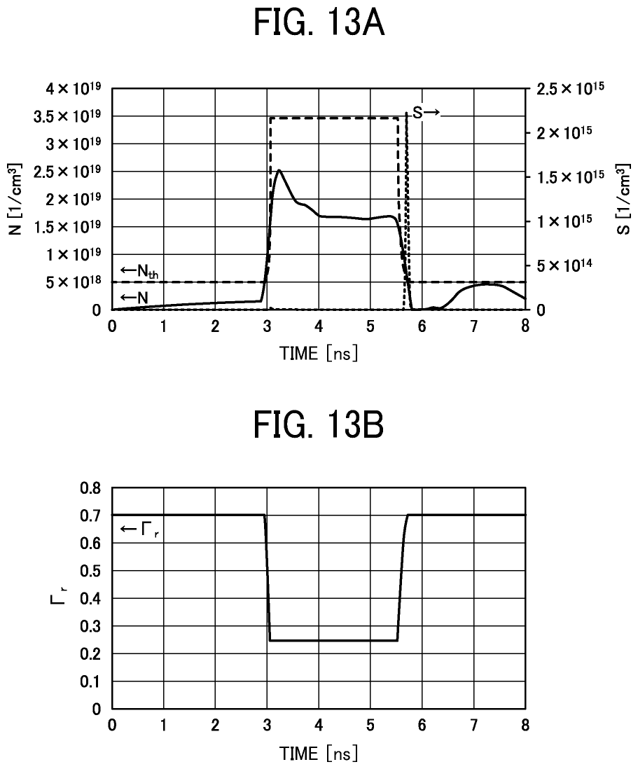

To analyze the results in detail, FIGS. 13A and 13B present simulation results of the carrier density N, the threshold carrier density Nₜₕ, the photon density S, and the optical confinement factor Γᵣ in the lateral direction under the condition of the pulse width being 2.5 ns. FIG. 13A presents simulation results of the carrier density N, the threshold carrier density Nₜₕ, and the photon density S. FIG. 13B presents a simulation result of the optical confinement factor Γᵣ in the lateral direction.

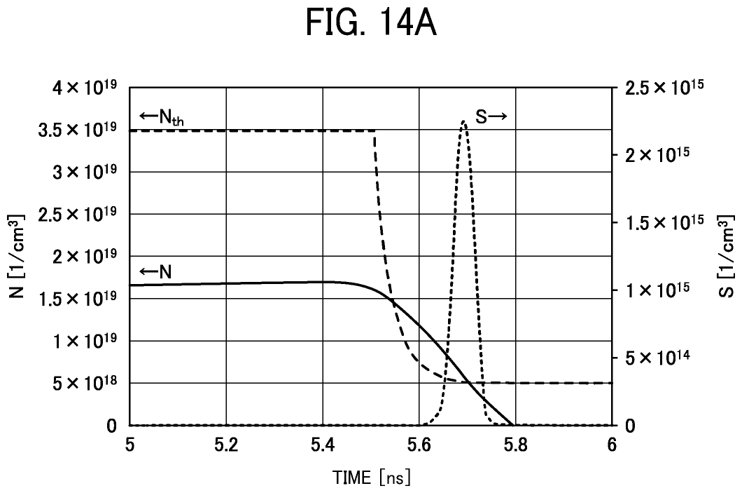

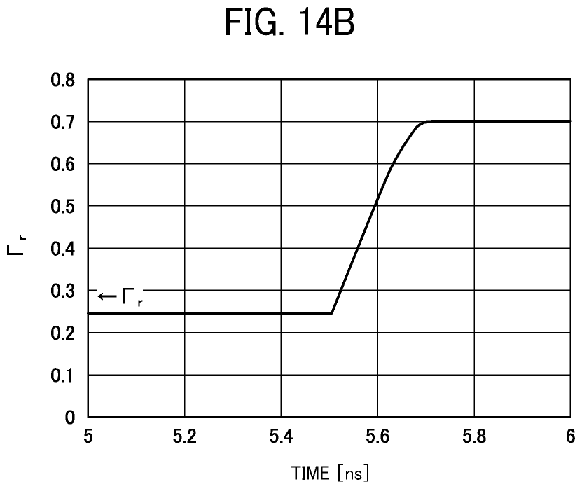

Since the optical confinement factor Γᵣ in the lateral direction is the function of the carrier density N, the optical confinement factor Γᵣ in the lateral direction decreases in a range from 3 ns to 5.5 ns in which the pulse current is injected. Within this range, the threshold carrier density Nₜₕ increases along with a decrease in the optical confinement factor Γᵣ in the lateral direction, and N<Nₜₕ is established. Hence induced emission is less likely to occur, and the photon density S does not increase. When the injection of the pulse current starts decreasing at the time point of about 5.5 ns, the optical confinement factor Γᵣ in the lateral direction increases again, and in the process, the photon density S appears in a pulse form. FIGS. 14A and 14B are graphs in which the time axis in the range from 5 ns to 6 ns in FIGS. 13A and 13B is expanded.

When the injection of the pulse current starts decreasing at the time point of about 5.5 ns, the carrier density N starts decreasing. At the same time, the optical confinement factor Γᵣ in the lateral direction increases, and the threshold carrier density Nₜₕ decreases. Since the decrease in the threshold carrier density Nₜₕ is faster than the decrease in the carrier density N, there is a period in which N>Nₜₕ is established in the process of the decrease in the carrier density N. During this period, the photon density S first increases due to spontaneous emission, and when the photon density S increases by a certain degree, induced emission becomes dominant, and the photon density S rapidly increases. At the same time, the carrier density N rapidly decreases, and when N<Nₜₕ is established again, the photon density rapidly decreases.

As described above, the phenomenon in which the optical pulse is output when the injection of the pulse current is stopped as a trigger can be reproduced by the simulation.

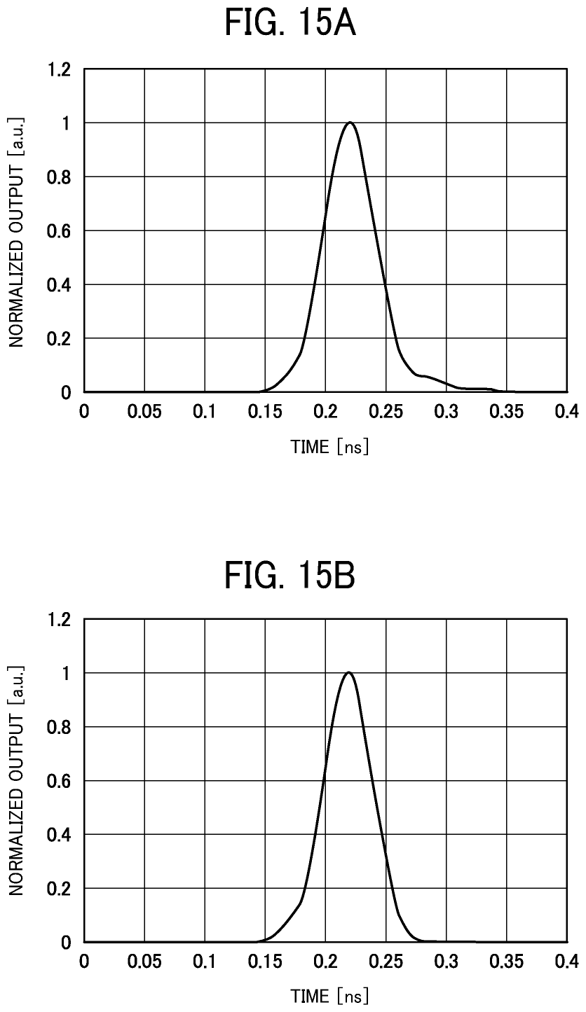

The rising time of the optical pulse decreases as the threshold carrier density Nₜₕ decreases faster than the carrier lifetime. That is, based on Equation (6), the rising time decreases as the increase in the lateral optical confinement factor Γᵣ is faster. The attenuation time of the optical pulse depends on the photon lifetime. FIGS. 15A and 15B are graphs presenting examples of an actual measurement result and a simulation result of optical pulses. FIG. 15A presents an actual measurement result. FIG. 15B presents a simulation result.

When the pulse width is defined as a time width of 1/e² or more of the peak value, the obtained optical pulse width is 86 ps in the actual measurement result in FIG. 15A, and is 81 ps in the simulation result in FIG. 15B. In this case, e is a natural logarithm. With this model, the width of the optical pulse is shorter than the pulse current to be injected, and can be decreased without being limited by the time width of the pulse current to be injected.

In the first example, a continuous optical pulse train is less likely to be generated after the optical pulse output is generated. This is because the injection of the pulse current decreases when the optical pulse is generated, and the relaxation oscillation is less likely to be generated.

Moreover, tail light is less likely to be generated after the optical pulse output is generated. This is because the injection of the pulse current decreases after the optical pulse is generated, and the carrier density is less likely to increase.

Furthermore, since the optical pulse is output immediately after the injection of the pulse current is stopped, the timing at which the optical pulse is output can be desirably controlled.

Furthermore, the width of the optical pulse generated according to the first example is smaller than the width of the injected pulse current. Even when the current is increased, the pulse current width does not have to be decreased, and hence the pulse current width is less likely to be affected by parasitic inductance.

A plurality of surface emitting lasers 100 according to the first example may be arranged in parallel to form a surface emitting laser array, and optical pulses may be simultaneously output, thereby obtaining a larger optical peak output. The current injected into the surface emitting laser array is larger than the current injected into one surface emitting laser 100; however, since the width of the optical pulse output from the surface emitting laser 100 is smaller than the width of the injected pulse current, the optical pulse with a small width can be output.

The pulse width of the light output from the surface emitting laser 100 according to the first example is not limited; however, the pulse width is, for example, 1 ns or less, preferably 500 ps or less, and more preferably 100 ps or less.

In the first example, the thickness of the oxidized region 151 at a position 3 μm separated outward from the inner edge of the inner region 154, that is, at a position 3 μm separated outward from a tip end portion of the boundary between the non-oxidized region 152 and the oxidized region 151, is preferably twice or less the thickness of the non-oxidized region 152. For example, when the thickness of the non-oxidized region 152 is 31 nm, the thickness at the position 3 μm separated outward from the inner edge of the inner region 154 is preferably 62 nm or less, and may be 54 nm. When the distance (oxidation distance) from the side surface of the mesa 180 to the inner edge of the oxidized region 151 is in a range from 8 μm to 11 μm, the distance of 3 μm corresponds to 28% to 38% of the oxidation distance. When the thickness of the oxidized region 951 and the thickness of the non-oxidized region 152 were measured at the position 3 μm separated outward from the inner edge of the oxidized region 951 in actual measurement of the above-described reference example, the thickness of the oxidized region 951 was 79 nm, and the thickness of the non-oxidized region 152 was 31 nm.

The thickness of the oxidized region 951 was 2.55 times the thickness of the non-oxidized region 152. As a result of comparative evaluation of various elements having oxidized confinement structures, the inventors have found that the optical confinement factor Γᵣ in the lateral direction decreases when the ratio is 2 or less, and short-pulse light with a high output and no tailing is likely to be obtained.

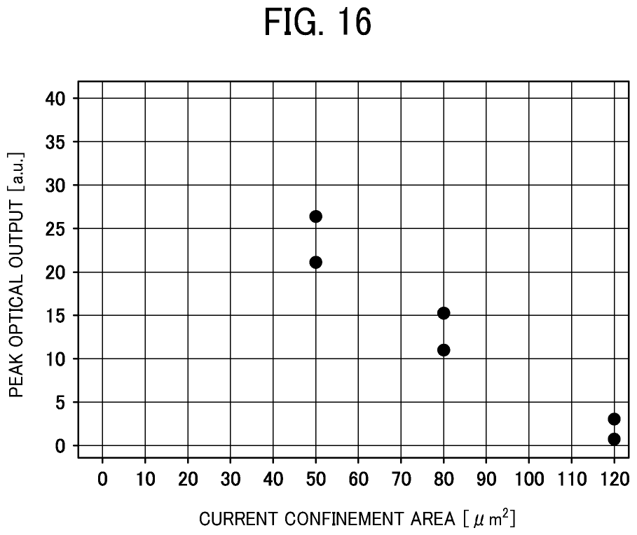

The area (current confinement area) of the non-oxidized region 152 in plan view is desirably 120 μm2 or less. As a result of comparative evaluation of various elements of the non-oxidized region 152, the inventors have found that the phenomenon in which the optical pulse is output immediately after the injection of the pulse current is stopped is less likely to occur when the non-oxidized region 152 has an area exceeding 120 μm2. Moreover, it was found that an optical pulse with a high peak output is likely to be obtained as the non-oxidized region 152 is smaller. FIG. 16 is a graph presenting measurement results of a peak optical output for a sample in which the area of a non-oxidized region is in a range from 50 μm2 to 120 μm2.

As can be seen from the principle described in the first example above, the number of carriers accumulated in the active layer is preferably increased to increase the obtained short pulse output. Further, N>Nₜₕ is to be established in as short a time as possible after the current injection is stopped.

When the current injection is stopped, the carrier density decreases at the central portion in the vicinity of the active layer in the current confinement structure due to diffusion, spontaneous emission, and non-radiative recombination of carriers, and the transverse mode distribution whose spread is due to the plasma effect becomes a distribution in the central portion of the device. As a result, N>Nₜₕ is established, and short pulse oscillation occurs. During the oscillation of short pulses, the carrier loss is to be reduced to increase pulse output power.

In the above example, the current injection for obtaining an output serves to reduce oscillation of light due to refractive index changes resulting from the plasma effect, accumulated carriers partly disappear until the short pulse oscillation occurs. If the refractive index can be changed by means other than the plasma effect irrespective of the amount of currents to be injected injection and the amount of accumulated carriers, the accumulated carriers can be effectively converted into short-pulse output to be extracted, and short-pulse operation with higher efficiency and higher output can be performed.

As a means for externally modulating the refractive index, an electric field effect of a multi-quantum well structure is effective. In the multiple-quantum well structure, a change in the refractive index, that is, a decrease in refractive index can be obtained by applying an electric field in a direction perpendicular to the well surface.

A change in refractive index due to an electric field in a quantum-well structure is reported in, for example, Non-Patent Document 1, Non-Patent Document 2, Non-Patent Document 3, and Non-Patent Document 4. In Non-Patent Document 1, it is theoretically reported that a value of (Δn/n)/E=3×10⁻⁸ cm/V is obtained in a quantum-well structure composed of InGaAsP and InP having 30 nm thicknesses. For example, when an electric field of 100 kV/cm is applied (bias of 0.3 V with respect to the quantum-well of 30 nm), Δn/n is 3×10⁻³ (Δn/n=3×10⁻³), that is, Δn is approximately equal to −9×10⁻³ (Δn≈−9×10⁻³).

In Non-Patent Documents 2 and 3, (Δn/n)/E was actually observed to be 4×10⁻¹ cm/V at room temperature in a multi-quantum-well structure composed of GaAs having a thickness of 10 nm and AlAs having a thickness of 30 nm. This means that Δn is approximately equal to −4×10⁻² (Δn≈−4×10⁻²) when an electric field of 100 kV/cm is applied, and a value greater than the theoretical value in Non-Patent Document 1 is observed. Non-Patent Document 3 indicates that a red shift of interband transition energy and a change in refractive index due to the quantum-confined Stark effect caused by application of an electric field. In Non-Patent Document 4, a value of Δn approximately equal to −3×10⁻² (Δn≈−3×10⁻²) is reported as an experimental result.

As described above, the electric field effect of the multiple quantum-well structure enables a refractive index change equal to or greater than that of the plasma effect of Δn approximately equal to −1×10⁻² order in a realistically applied electric field of 100 kV/cm. This enables further improvement of the control of the short-pulse operation and the pulse output power.

When an electric field is applied to such a multi-quantum well structure arranged near the resonator, the refractive index of the multi-quantum well portion decreases and acts in a direction to cancel the effective refractive index difference Δn0 obtained by the oxide structure as presented in FIGS. 8A and 8B. In other words, another means, in addition to the plasma effect, for changing the effective refractive index difference Δn is available. Further, controlling the effective refractive index difference Δn by using the electric field applied to the multiple-quantum well enables control of the timing of oscillation of a short pulse which is laser oscillation.

### First Embodiment

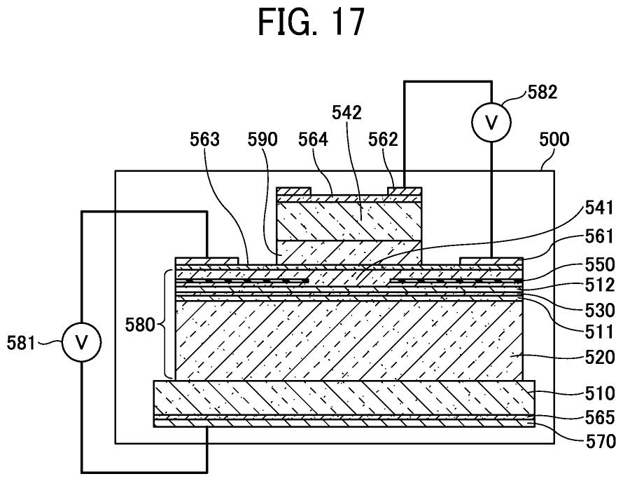

Embodiments of the present disclosure are described below with reference to the accompanying drawings. The first embodiment relates to a surface emitting laser. FIG. 17 is a cross-sectional view of a top-surface emitting laser 500 according to the first embodiment, which is produced based on the above-described principle and has wavelengths in the 940 nm band.

The surface emitting laser 500 is, for example, a vertical-cavity surface-emitting lasers (VCSEL) using oxidation confinement, as in the first example. The surface emitting laser 500 includes an n-type GaAs substrate 510, an n-type DBR 520, an active layer 530, a first p-type DBR 541, an oxidized confinement layer 550, a contact layer 563, a contact layer 565, a first upper electrode 561, and a lower electrode 570. The n-type DBR 520 (the lower reflector) underlies the active layer 530. The surface emitting laser 500 further includes resonator spacer layers 511 and 512, a multi-quantum well structure 590, a second p-type DBR 542, and a second upper electrodes 562. In FIG. 17, a cylindrical mesa post 580 includes the n-type DBR 520, the resonator spacer layer 512, the active layer 530, the resonator spacer layer 511, the oxidized confinement layer 550, the first p-type DBR 541, and the contact layer 563. The multi-quantum well structure overlies the active layer 530. A first power supply device 581 and a second power supply device 582 each supply a current and an electric field to the surface emitting laser 500. Within the context of the present disclosure, if a first layer is stated to be “overlaid” on, or “overlying” a second layer, the first layer may be in direct contact with a portion or all of the second layer, or there may be one or more intervening layers between the first and second layer, with the second layer being closer to the substrate than the first layer.

The n-type DBR 520 as a lower reflector overlies the n-type GaAs substrate 510. The n-type DBR 520 is composed of 40 pairs of n-type Al_{0.1}Ga_{0.9}As and Al_{0.9}Ga_{0.1}As. The resonator spacer layer 511 overlies the n-type DBR 520. The resonator spacer layer 511 is made of Al_{0.2}Ga_{0.8}As. The active layer 530 overlies the resonator spacer layer 511. The active layer 530 is a multiple-quantum well active layer having InGaAs as well layers and AlGaAs as barrier layers. The resonator spacer layer 512 overlies the active layer 530. The resonator spacer layer 512 is made of Al_{0.2}Ga_{0.8}As. The first p-type DBR 541 as a first upper reflector (or an upper reflector) overlies the resonator spacer layer 512. The first p-type DBR 541 is composed of four pairs of p-type Al_{0.1}Ga_{0.9}As and Al_{0.9}Ga_{0.1}As. The contact layer 563 overlies the first p-type DBR 541. The contact layer 563 is made of p-type GaAs.

The surface emitting laser 500 further includes an undoped multi-quantum well structure 590 for refractive-index modulation, the second p-type DBR 542, and a contact layer 564. The multi-quantum well structure 590 overlies the contact layer 563. The multi-quantum well structure 590 includes multiple semi-conductor layers including, for example, 20 pairs of InGaAs and AlGaAs. The second p-type DBR 542 as a second upper reflector overlies the multi-quantum well structure 590. The second p-type DBR 542 is composed of 16 pairs of p-type Al_{0.1}Ga_{0.9}As and Al_{0.9}Ga_{0.1}As. The contact layer 564 overlies the second p-type DBR 542. The contact layer 564 is made of p-type GaAs. The contact layer 565 overlies the back surface of the n-type GaAs substrate 510. The contact layer 565 is made of n-type GaAs.

In the multi-quantum well structure 590 for refractive index modulation, the energy between bands is set to be approximately equal to the photon energy of the oscillation wavelength with an electric field applied. When an electric field is applied, the effective band gap energy decreases due to the quantum confined Stark effect. With such a reduction in the band gap energy, red-shifting the wavelength of the absorption edge allows light having a longer wavelength to be absorbed. When the effective band gap energy at the time of applying the electric field is larger than the photon energy, the absorption loss can be reduced. When the effective band gap energy is smaller than the photon energy, the oscillation can be further reduced by the absorption loss.

The oxidized confinement layer 550 in the first p-type DBR 541 type DBR 541 is formed by forming a p-type AlAs selectively oxidized layer having a thickness of 20 nm in the first p-type DBR 541 before forming the cylindrical mesa post 580 and then oxidizing the p-type AlAs selectively oxidized layer in heated water vapor. The cylindrical mesa post 580 includes the n-type DBR 520, the resonator spacer layers 511 and 512, the active layer 530, the first p-type DBR 541, and the contact layer 563. The first p-type DBR (the first upper reflector) is columnar. The “columnar” shape includes a prism such as a square, a rectangle, and a hexagon. The multi-quantum well structure 590, the second p-type DBR 542, and the contact layer 564 each have a cylindrical shape. The shape of the mesa post is not limited to a circle, and may be any shape such as a square, a rectangle, or a hexagon. In other words, the columnar shape includes a square, rectangle, and a hexagon.

The lower electrode 570 overlies the back surface of the contact layer 565 overlying the n-type GaAs substrate 510. The first upper electrode 561, which is ring-shaped, overlies the contact layer 563 overlying the first p-type DBR 541. The second upper electrode 562, which is ring-shaped, overlies the surface of the contact layer 564 overlying the second p-type DBR 542. The first power supply device 581 injects a current into the active layer via a first electrode pair including the first upper electrode 561 and the lower electrode 570. The second power supply device 582 applies an electric field to the multi-quantum well structure 590 for refractive index modulation via a second electrode pair including the first upper electrode 561 and the second upper electrode 562. This duration is referred to as an electric-field application period. Notably, although the second p-type DBR 542 may be undoped, the voltage applied from the second power supply device 582 to the multi-quantum well structure 590 is reduced by undoping the second power supply device 582. This duration is referred to as an electric-field decrease period.

Next, the operation principle of the surface emitting laser 500 will be described in detail. First, the second power supply device 582 applies an electric field to the multi-quantum well structure 590 in advance. When an electric field is applied, the effective refractive index of the central portion of the device decreases with respect to the effective index difference Δn0 obtained from the oxidized confinement layer 550 during application of no electric field. Thus, the effective refractive index difference Δn is smaller than the effective refractive index difference Δn0.

Next, the first power supply device 581 starts injecting a current into the active layer 530. In other words, at least part of the current injection period is included in at least part of the electric-field application period. At this time, the effective refractive index difference Δn further decreases due to the plasma effect. Such two actions described above reduce the transverse mode distribution in the central portion of the device, and oscillation is suppressed, and causes carriers to be accumulated in the active layer 530 whose oscillation is reduced.

When the electric field effects of the multi-quantum well structure is used in combination, the effective refractive-index difference Δn0 obtained from the oxidized confinement layer 550 is set to be slightly larger. Then, the change in refractive index due to the electric field effect and the plasma effect of the carriers in the multi-quantum well structure 590 is combined to establish the relation between the threshold carrier density Nₜₕ and the carrier density N as presented in FIG. 13A. In other words, the oscillation is reduced by both the plasma effect and the electric field effect.

Next, when the second power supply device 582 stops applying the electric field to the multi-quantum well structure 590 for refractive index modulation, the interband transition energy of the multi-quantum well structure 590 increases. In other words, the red-shift due to the quantum-confined Stark effect is eliminated, to cause transparency to the oscillation wavelength while increasing the effective refractive index difference Δn. With an increase in the effective refractive index difference Δn, the transverse mode distribution in the central portion of the device is increased to reduce the oscillation threshold and immediately cause short-pulse oscillation. At this time, if the first power supply device 581 also stops injecting currents into the active layer 530 at the same time of stopping the second power supply device 582, a larger change in refractive index can be obtained.

When the oscillation is reduced by the plasma effect alone, the effective refractive index difference Δn which has been reduced by the plasma effect after the stop of the current injection into the active layer 530 is recovered to allow the oscillation as described below. In other words, the carriers accumulated in the active layer 530 are recovered by diffusion from the current injection path or reduction by recombination process in the active region. However, carriers that do not contribute to the oscillation during that time are partly lost.

However, in the first embodiment, since the refractive index change is immediately caused by the control of the electric field applied from the second power supply device 582 to the multi-quantum well structure 590, the amount of carriers that do not contribute to oscillation can be significantly reduced. This enables the peak output especially at the start of oscillation to be greatly improved. Notably, the effective refractive index difference Δn0 due to the oxidized confinement layer 550 can be changed by changing the thicknesses of the oxidized confinement layer 550, and can be increased by thickening the oxidized confinement layer 550.

The effective refractive index difference Δn0 obtained from the oxidized confinement layer 550 is set so that oscillation starts when the application of an electric field to the multi-quantum well structure 590 is stopped. In other words, oscillation is not performed during the electric-field application period, but is performed during the electric-field decrease period. The first embodiment with such a configuration combines the plasma effect with the electric field effect. This configuration enables reduction of the oscillation more significantly than the case of using the plasma effect alone. Thus, the first embodiment enables more carriers to be accumulated in the active layer and a higher peak output power of the short-pulse oscillation.

As described above, as the amount of change in the refractive index due to the electric field effect increases, a larger effect of reducing oscillation can be obtained, and the number of accumulated carriers can be increased. Further, the effective refractive index difference Δn0 obtained from the oxidized confinement layer 550 is increased with the oscillation reduction effect maintained to enable an increase in the amount of change in the oscillation threshold value when the application of the electric field is stopped. This enables a reduction in the number of invalid carriers to disappear before the start of oscillation of the short pulse, and thus achieve a higher output power.

Such effects can be obtained by placing the multi-quantum well structure 590 at any position in the path of the laser light to obtain the refractive index change due to the electric field effect. Further, the multi-quantum well structure 590 can be closer to the active layer 530 or the amount of change in the refractive index due to the electric field effect on the multi-quantum well structure can be increased by increasing the number of quantum wells.

Furthermore, since the optical pulse is output immediately after the injection of the pulse current is stopped, the timing at which the optical pulse is output can be desirably controlled.

In addition, since the number of accumulated carriers can be increased and invalid carriers not contributing to oscillation can be reduced, a higher output power can be obtained.

In the first embodiment, a continuous optical pulse train is less likely to be generated after the optical pulse output is generated. This is because the injection of the pulse current decreases when the optical pulse is generated, and the relaxation oscillation is less likely to be generated.

Moreover, tail light is less likely to be generated after the optical pulse output is generated. This is because the injection of the pulse current decreases after the optical pulse is generated, and the carrier density is less likely to increase.

Furthermore, the width of the optical pulse generated according to the first embodiment is smaller than the width of the injected pulse current. Even when the current is increased, the pulse current width does not have to be decreased, and hence the pulse current width is less likely to be affected by parasitic inductance.

Similarly to the first example, multiple surface emitting lasers 500 according to the first embodiment may be arranged in parallel to form a surface emitting laser array, and optical pulses may be simultaneously output, thereby obtaining a larger optical peak output. The current injected into the surface emitting laser array is larger than the current injected into one surface emitting laser 500; however, since the width of the optical pulse output from the surface emitting laser 500 is smaller than the width of the injected pulse current, the optical pulse with a small width can be output.

Similarly to the first example, the pulse width of the light output from the surface emitting laser 500 according to the first embodiment is not limited; however, the pulse width is, for example, 1 ns or less, preferably 500 ps or less, and more preferably 100 ps or less.

In the first embodiment, when the oxidized confinement layer 550 has a configuration that is the same as that of the first example, the thickness of the oxidized region 551 at a position 3 μm separated outward from the inner edge of the inner region 554, that is, at a position 3 μm separated outward from a tip end portion of the boundary between the non-oxidized region 552 and the oxidized region 551, is preferably twice or less the thickness of the non-oxidized region 552.

Similarly to the first example, in the first embodiment, as described with reference to FIG. 16 of the first example, the area (current confinement area) of the non-oxidized region 552 in plan view is desirably 120 μm2 or less.

### Second Embodiment

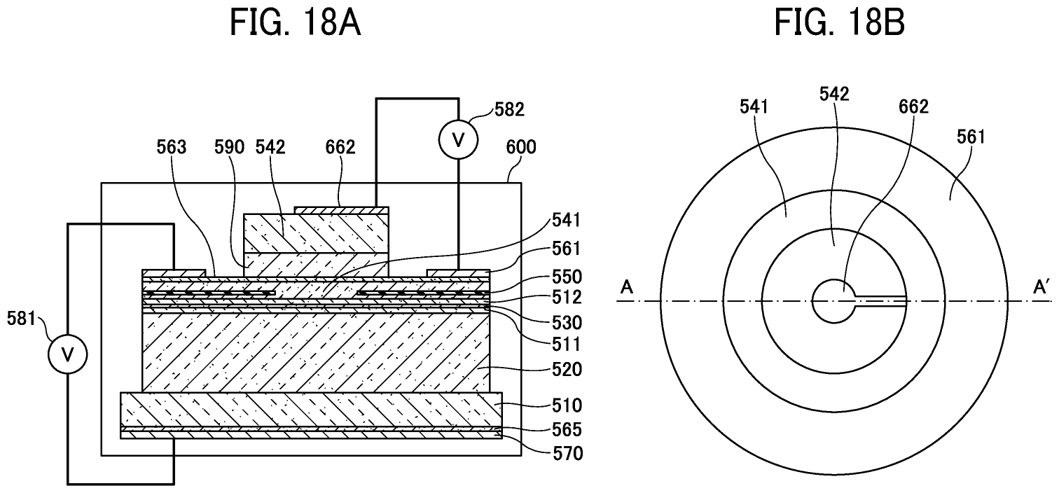

Next, a second embodiment will be described. The second embodiment relates to a surface emitting laser. FIGS. 18A and 18B are cross-sectional views of a surface emitting laser 600 according to the second embodiment.

Since the surface emitting laser 600 according to the second embodiment is the same as that of the first embodiment except for a second upper electrode 662 overlying the second p-type DBR 542, the description of components other than the second upper electrode 662 will be omitted.

Since the surface emitting laser 600 is a top-surface emitting laser, the second upper electrode 662 overlying the second p-type DBR 542 is transparent to not inhibit transmission of a laser beam. FIG. 18B is a top view of the surface emitting laser 600. FIG. 18A is a cross section taken along line A-A′ in FIG. 18B. The second upper electrode 662 is circular and, as illustrated in FIG. 18B, is located at the central portion of the cylindrical the first p-type DBR 541 in plan view. As illustrated in FIG. FIG. 18A, the second upper electrode 662 is led out from the central portion and is connected to the second power supply device 582 at an outer portion that does not inhibit transmission of a laser beam. With the electrode configuration in FIGS. 18A and 18B, an electric field can be applied in a concentrated manner to the multi-quantum well structure for refractive index modulation in the central portion of the surface emitting laser 600 in plan view. This enables a selective reduction in the effective refractive index in the central portion of the device.

Such a reduction in the effective refractive index difference in the central portion further enables a reduction in the intensity of the transverse mode distribution in the central portion of the device and thus achieves an effective reduction in the effective refractive index difference Δn. Further, the configuration in which the second p-type DBR 542 is undoped and the contact layer overlying the second p-type DBR 542 is eliminated prevents or reduce the electric field from being spread out in the lateral direction and further improve the selectivity. Alternatively, the second p-type DBR 542 may be made of a dielectric material such as SiN or SiO₂.

As described above, the second embodiment exhibits the same effects as the first embodiment. Further, providing the second upper electrode at the central portion of the device allows an increase in the amount of change in the refractive index and thus achieves a higher laser output power.

### Third Embodiment

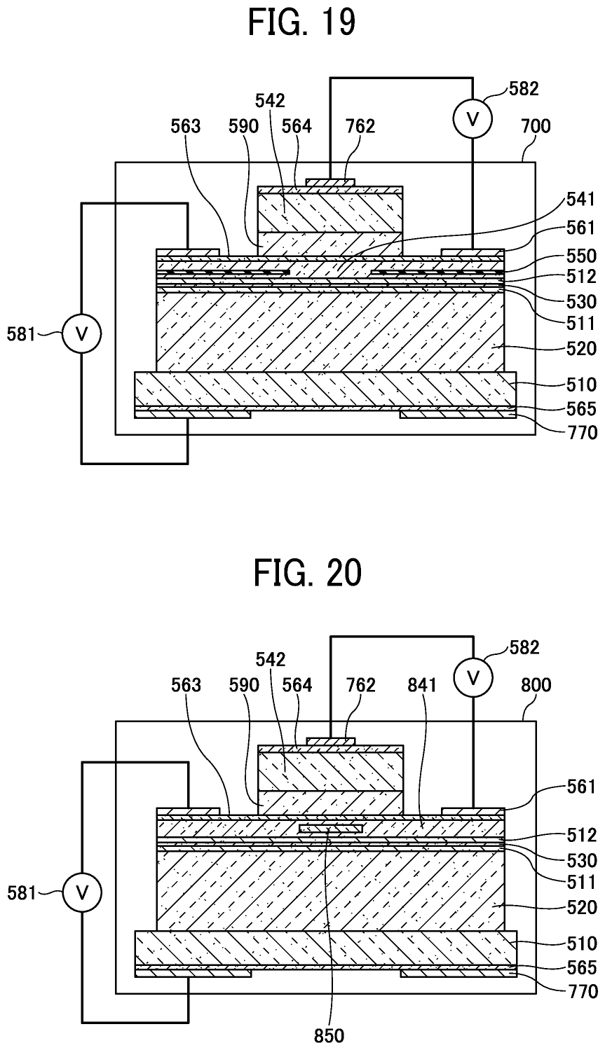

Next, a third embodiment will be described. The third embodiment relates to a surface emitting laser. FIG. 19 is a cross-sectional view of a surface emitting laser 700 according to the third embodiment.

The surface emitting laser 700 is a back-surface emitting laser with an oscillation wavelength of 940 nanometer (nm) band. In the surface emitting laser 700 in FIG. 19, the number of pairs of upper multilayer film reflectors composed of the first p-type DBR 541 and the second p-type DBR 542 is 40 in total, and the number of pairs of lower multilayer film reflectors composed of the n-type DBR 520 is 20. The surface emitting laser 700 emits a laser bream in a direction to the substrate, i.e., the back surface.

The lower electrode 770, which is a portion to emit a laser beam outward, has an opening that allows extraction of optical output. The second p-type DBR 542 is provided with a second upper electrode 762 in the central portion of the device, allowing an electric field to be selectively applied to the multi-quantum well structure 590 for the refractive index modulation in the central portion of the device. The electrode in the central portion of the device enables a reduction in the effective refractive index of the central portion of the device in the same manner as in the second embodiment as described above.

Such a reduction in the effective refractive index difference in the central portion further enables a reduction in the intensity of the transverse mode distribution in the central portion of the device and thus achieves an effective reduction in the effective refractive index difference Δn. Further, the configuration in which the second p-type DBR 542 is undoped and the contact layer overlying the second p-type DBR 542 is eliminated further prevents or reduce the electric field from being spread out in the lateral direction. This further facilitates the selectivity of the operation. Alternatively, the second p-type DBR 542 may be made of a dielectric material such as SiN or SiO₂.

As described above, the third embodiment exhibits the same effects as the second embodiment.

### Fourth Embodiment

Next, a fourth embodiment will be described. The fourth embodiment relates to a surface emitting laser. FIG. 20 is a cross-sectional view of a surface emitting laser 800 according to the fourth embodiment.

The surface emitting laser 800 according to the fourth embodiment is, for example, a VCSEL provided with a current confinement structure incorporating a buried tunnel junction (BTJ). The surface emitting laser 800 is different from the back-surface emitting laser 700 of the third embodiment in that the surface emitting laser 800 includes a buried tunnel junction 850, instead of the selectively-oxidized structure, in the current confinement structure.

The buried tunnel junction 850 is configured as follows. During the formation of the first p-type DBR 841, a p⁺⁺GaAs layer doped with p higher in concentration than that of the first p-type DBR 841 and an n⁺⁺GaAs layer doped with p higher in concentration than that of the n-type DBR 520 are grown. After the growth of that layers is once stopped, the two layers except for the central portion of the device are eliminated by selectively wet etching, so as to form the buried tunnel junction 850. Then, the first p-type DBR 841 is further grown on the formed buried tunnel junction 850.

When a forward bias is applied to the lower electrode 770 and the first upper electrode 561, which are electrodes for injecting current into the active layer 530, a reverse bias is applied to p⁺⁺GaAs layer and the n⁺⁺GaAs layer. As a result, electrons band-to-band tunnels from p⁺⁺GaAs layer to the n⁺⁺GaAs layer, generating positive holes in p⁺⁺GaAs layer. With the holes, the electrons are injected to the active layer 530.

The buried tunnel junction portion has a small refractive index difference due to the difference in the Al composition of the AlGaAs material in the lateral direction. Weak lateral optical confinement is formed based on such a refractive index difference. The lateral optical confinement has a degree that changes the effective refractive index difference Δn with a change in refractive index due to a plasma effect of carriers and an electric-field effect of the multiple-quantum well and enables oscillation of a short pulse.

As described above, the fourth embodiment exhibits the same effects as the third embodiment.

### Fifth Embodiment

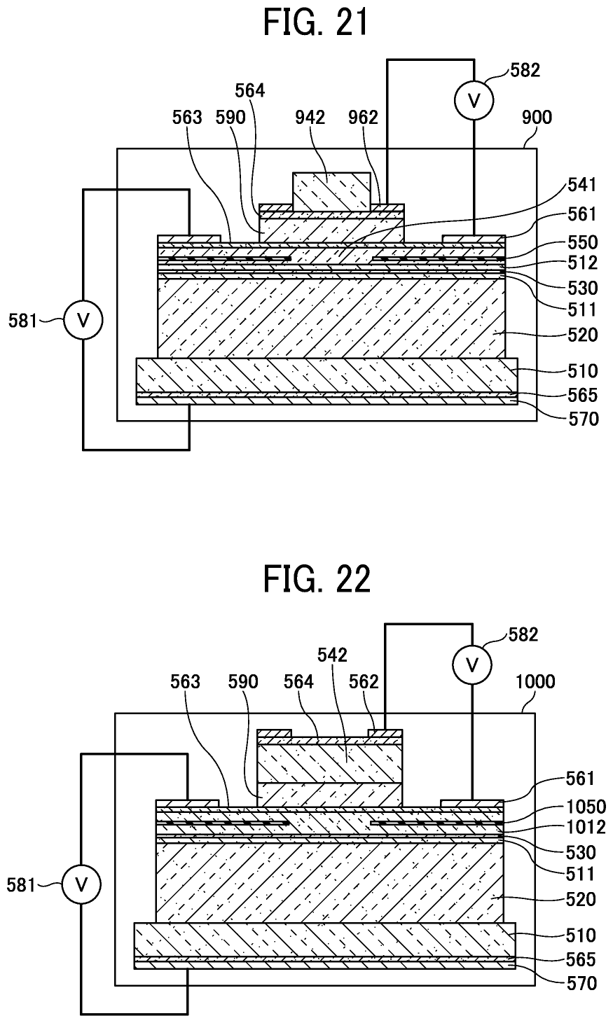

Next, a fifth embodiment will be described. The fifth embodiment relates to a surface emitting laser. FIG. 21 is a cross-sectional view of a surface emitting laser 900 according to the fifth embodiment.

The surface emitting laser 900 according to the fifth embodiment is obtained by modifying the second p-type DBR and the second upper electrode in the top-surface emitting laser 500 according to the first embodiment. In the surface emitting laser 900, the second upper electrode 962 overlying the upper surface of the multi-quantum well structure 590 instead of the upper surfaces of the second p-type DBR 942. With such a structure, an electric field can be applied to the multi-quantum structure 590 without involving the second p-type DBR 942. This configuration of the fifth embodiment allows a stronger electric field to be applied to the multi-quantum well structure 590 than the first embodiment. Thus, the fifth embodiment enables a larger amount of change in refractive index due to the electric field effects.

As described above, the fifth embodiment exhibits the same effects as the first embodiment. Further, a larger amount of change in refractive index achieves a higher laser output power.

### Sixth Embodiment

Next, a sixth embodiment will be described. The sixth embodiment relates to a surface emitting laser. FIG. 22 is a cross-sectional view of a surface emitting laser 1000 according to the sixth embodiment.

The surface emitting laser 1000 according to the sixth embodiment is different from the surface emitting laser 500 according to the first embodiment in that a resonator spacer layer 1012 is thick, instead of the first p-type DBR 541. Further, in the surface emitting laser 1000 includes an oxidized confinement layer 1050 in the resonator spacer layer 1012. This configuration also exhibits the same effects as those of the first embodiment.

In the first to sixth embodiments, a multi-quantum well structure for obtaining the electric field effects is between the active layer and the second p-type DBR. However, no limitation is intended thereby. The multi-quantum well structure may be at any position in the laser optical path to allow a change in refractive index due to the electric field effects. This also exhibits the same effects as those of the first to sixth embodiments.

### Seventh Embodiment

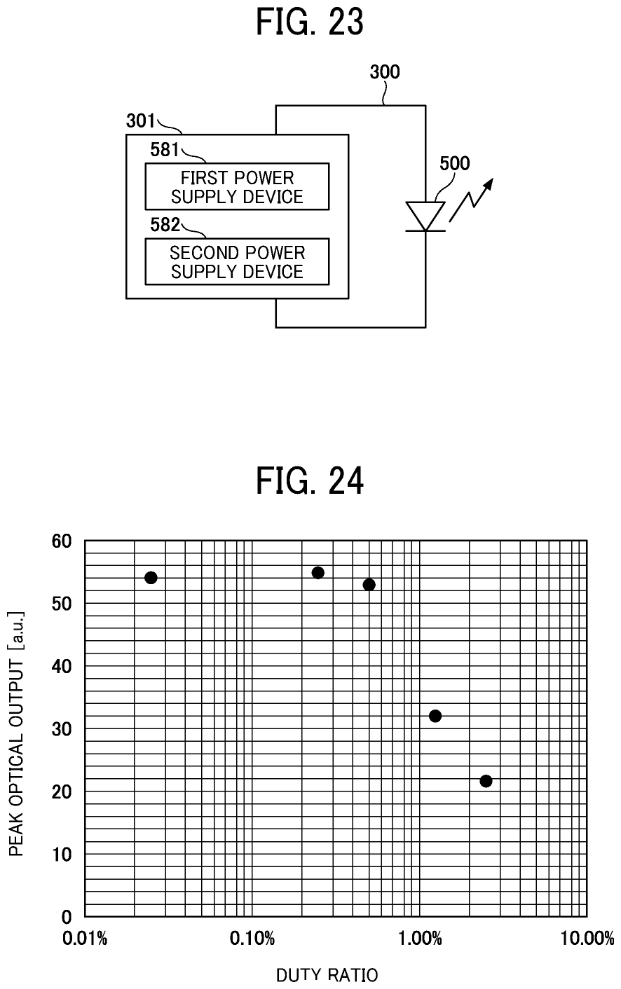

Next, a seventh embodiment will be described. The seventh embodiment relates to a laser device. FIG. 23 is a diagram of a laser device 300 according to the seventh embodiment.

The laser device 300 according to the seventh embodiment includes the surface emitting laser 500 according to the first embodiment, and a power supply device 301. The power supply device 301 includes a first power supply device 581 and a second power supply device 582. The first power supply device 581 is connected to the first upper electrode 561 and the lower electrode 570. The second power supply device 582 is connected to the first upper electrode 561 and the second upper electrode 562. The first power supply device 581 injects a current into the surface emitting laser 500, and the second power supply device 582 applies an electric field to the surface emitting laser 500.

The duty ratio of the injection of current from the first power supply device 581 is preferably 0.5% or less. That is, it is desirable that the current injection period and the current decrease period are repeated a plurality of times, and the ratio of the current injection period to the current decrease period is 0.5% or less. The duty ratio is a ratio of a period in which a current pulse is injected in a unit period. When t [s] denotes a pulse current width and f [Hz] denotes a repetition frequency of pulse current, the duty ratio corresponds to f×t (%). FIG. 24 is a graph presenting the relationship between the duty ratio and the peak output of optical pulses when the pulse current width is 2.5 ns.

As presented in FIG. 24, when the duty ratio is more than 0.5%, the optical peak output tends to decrease. Conceivable reasons for this are the following models. First, when the duty ratio is increased, the amount of heat generated in the current confinement region (non-oxidized region 152) by the injected pulse current increases. Thus, the temperature of the center portion where the current is concentrated rises with respect to the peripheral portion of the current confinement region, and a temperature difference is generated. Consequently, the refractive index of the center portion of the current confinement region increases by a thermal lens effect, and the optical confinement factor in the lateral direction increases. As the optical confinement factor in the lateral direction increases due to the thermal lens effect, the influence of a change in refractive index due to the carrier plasma effect generated by an increase or a decrease in pulse current decreases. Thus, the phenomenon in which the optical pulse is output immediately after the injection of the pulse current is stopped is less likely to occur. In contrast, when the duty ratio is 0.5% or less, the influence of the change in refractive index due to the thermal lens effect is sufficiently small, and the change in refractive index derived from the confinement structure is dominant, and thus the peak output is considered to be substantially constant and not changed.

In one example, instead of the surface emitting laser 500 according to the first embodiment, the surface emitting laser 600 according to the second embodiment or the surface emitting laser 1000 according to the sixth embodiment may be used.

### Eighth Embodiment

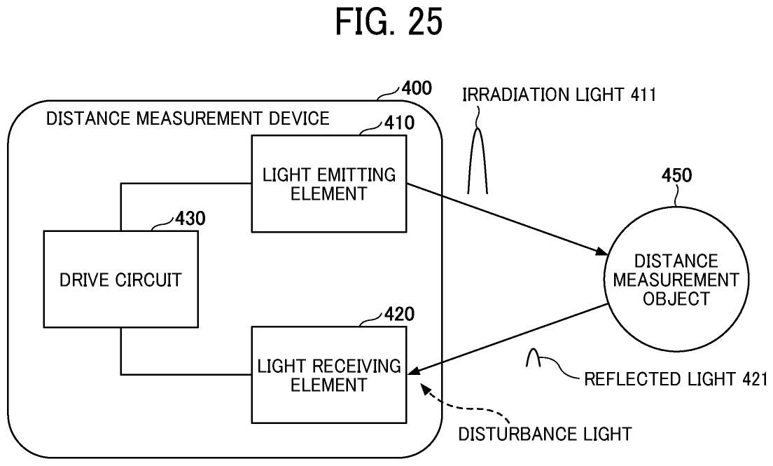

Next, a fifth embodiment will be described. The eighth embodiment relates to a distance measurement device. FIG. 25 illustrates a distance measurement device 400 according to the eighth embodiment. The distance measurement device 400 is an example of a detection device.

The distance measurement device 400 according to the eighth embodiment is a distance measurement device based on a time of flight (TOF) method. The distance measurement device 400 includes a light emitting element 410, a light receiving element 420, and a drive circuit 430. The light emitting element 410 emits an emission beam (irradiation light 411) to a distance measurement object 450. The light receiving element 420 receives reflected light 421 from the distance measurement object 450. The drive circuit 430 drives the light emitting element 410 and detects the difference in time between the emission timing of the emission beam and the reception timing of the reflected light 421 by the light receiving element 420 to measure the distance of reciprocation to and from the distance measurement object 450.

The light emitting element 410 includes the surface emitting laser 100 according to the first embodiment or the surface emitting laser 500 according to the second embodiment. The repetition frequency of pulses is, for example, in a range from several kilohertz to several tens of megahertz.

The light receiving element 420 is, for example, a photodiode (PD), an avalanche photodiode (APD), or a single photon avalanche diode (SPAD). The light receiving element 420 may include a plurality of light receiving elements arranged in an array. The light receiving element 420 is an example of a detector.

In the distance measurement by the TOF method, it is desirable to separate a signal from a distance measurement object and noise from each other. When a farther distance measurement object is measured or when a distance measurement object with a lower reflectivity is measured, it is desirable to obtain a signal from the object using a light receiving element with a higher sensitivity. However, when a light receiving element with a higher sensitivity is used, the possibility of erroneously detecting background light noise or shot noise increases. To separate the signal and the noise from each other, the threshold value of the light receiving signal may be increased; however, it may be difficult to receive the signal light from the distance measurement object unless the peak output of the emission beam is increased by the amount by which the threshold value of the light receiving signal is increased. However, the output of the emission beam is limited by the safety standards for lasers.

The surface emitting laser 500 according to the first embodiment or the surface emitting laser 1000 according to the sixth embodiment can output optical pulses having a pulse width of about 100 ps. This is about 1/10 compared to the value ns of the optical pulse width output from the surface emitting laser of the related art. According to the distance measurement device according to the eighth embodiment, since the peak output allowable under the safety standard increases as the pulse width of the optical pulse decreases, both an increase in precision and an increase in distance can be attained while eye-safe is satisfied.

### Ninth Embodiment

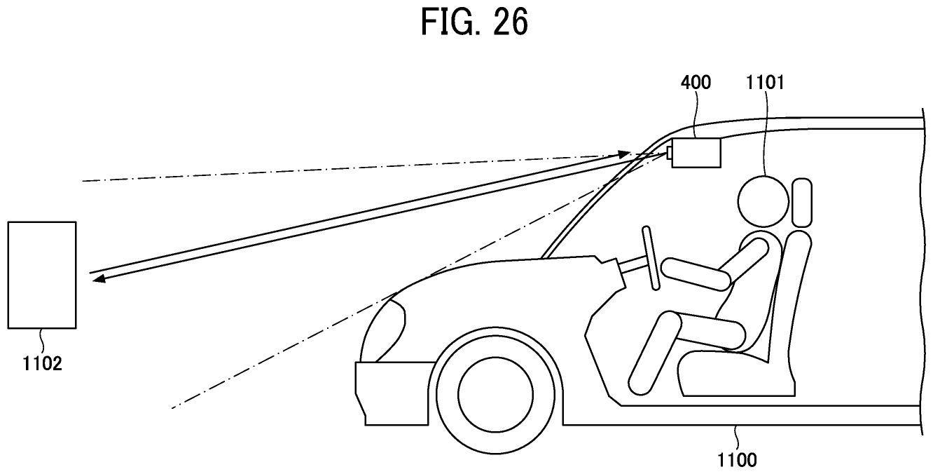

Next, a fifth embodiment will be described. The fifth embodiment relates to a mobile object. FIG. 26 illustrates an automobile 1100 as an example of a mobile object according to the ninth embodiment. The distance measurement device 400 described in the eighth embodiment is provided at an upper portion of a front surface of the automobile 1100 (for example, an upper portion of a windshield) as an example of a mobile object according to the ninth embodiment. The distance measurement device 400 measures the distance to an object 1102 around the automobile 1100. The measurement result of the distance measurement device 400 is input to a controller included in the automobile 1100, and the controller controls the operation of the mobile object based on the measurement result. Alternatively, the controller may provide warning indication on a display provided in the automobile 1100 to a driver 1101 of the automobile 1100 based on the measurement result of the distance measurement device 400.

As described above, in the ninth embodiment, since the distance measurement device 400 is provided in the automobile 1100, the position of the object 1102 in the periphery of the automobile 1100 can be recognized with high precision. The installation position of the distance measurement device 400 is not limited to the upper and front portion of the automobile 1100, and may be installed at a side surface or a rear portion of the automobile 1100. In this embodiment, the distance measurement device 400 is provided in the automobile 1100; however, the distance measurement device 400 may be provided in an aircraft or a ship. In one example, the distance measurement device 400 may be provided in a mobile object that moves autonomously without a driver, such as a drone or a robot.

Although the desirable embodiments and so forth have been described in detail, the present disclosure is not limited to the above-described embodiments and so forth, and various modifications and substitutions can be made without departing from the scope and spirit of the present disclosure as set forth in the claims.

This patent application is based on and claims priority to 35 U.S.C. § 119 (a) to Japanese Patent Application No. 2021-126012, filed on Jul. 30, 2021 in the Japan Patent Office, the entire disclosure of which is hereby incorporated by reference herein.

### REFERENCE SIGNS LIST

300 Laser device
400 Distance measurement device
500, 600, 700, 800, 900, 1000 Surface emitting laser
511, 512, 1012 Resonator spacer layer
520 N-type DBR
530 Active layer
541 First p-type DBR
542 Second p-type DBR
550, 1050 Oxidized confinement layer
551 Oxidized region
552 Non-oxidized region
561 First upper electrode
562, 662, 762, 962 Second upper electrode
563, 564, 565 Contact layer
570, 770 Lower electrode
580 Mesa post
590 Multi-quantum well structure
850 Tunnel junction
1100 Automobile (mobile object)

1. A surface emitting laser comprising:
an active layer;
multiple reflectors facing each other with the active layer therebetween;
a multi-quantum well structure including multiple semiconductor layers in an optical path of a laser beam emitted from the active layer and the multiple reflectors;
a first electrode pair connected to a first power supply to inject a current into the active layer; and
a second electrode pair connected to a second power supply to apply an electric field to the multi-quantum well structure in a direction perpendicular to a well surface of the multiple-quantum well structure,
wherein the surface emitting laser includes:
a current injection period in which the first power supply injects the current into the active layer;
a current decrease period after the current injection period, in which the current injected into the active layer is lower than the current injected during the current injection period;
an electric-field application period in which the second power supply applies the electric field to the multiple-quantum well structure; and
an electric-field decrease period after the electric-field application period, in which the electric field applied to the multi-quantum well structure is larger than the electric field applied during the electric-field application period,
wherein at least part of the current injection period is included in at least part of the electric-field application period, and
wherein the surface emitting laser does not oscillate a laser beam during the electric-field application period, and oscillates a laser beam during the electric-field decrease period.

2. The surface emitting laser according to claim 1,
wherein the multiple reflectors include:
a lower reflector underlying the active layer; and
a first upper reflector overlying the active layer,
wherein the multi-quantum well structure overlies the active layer.

3. The surface emitting laser according to claim 2,
wherein the first upper reflector is columnar, and
wherein one electrode of the second electrode pair is at least partly at a central portion of the first upper reflector in a plan view.

4. The surface emitting laser according to claim 1,
wherein the surface emitting laser outputs a pulse having a time axis shorter than a time axis of a pulse emitted during the current injection period.

5. A laser device comprising:
the surface emitting laser according to claim 1,
a first power supply connected to the first electrode pair; and
a second power supply connected to the second electrode pair.

6. The laser device according to claim 5,
wherein the electric-field application period starts before a start of the current injection period.

7. The laser device according to claim 5,
wherein the current decrease period starts at the same time as or after a start of the electric-field decrease period.

8. The laser device according to claim 5,
wherein the current injection period and the current decrease period are repeated multiple times, and
wherein a ratio of the current injection period to the current decrease period is 0.5% or less.

9. A detection device comprising:
the laser device according to claim 5; and
a detector to detect light emitted from the surface emitting laser and reflected by an object.

10. The detection device according to claim 9,
wherein the detection device calculates a distance to the object based on a signal from the detector.

11. A mobile object comprising the detection device according to claim 10.

12. A surface emitting laser driving method performed by a surface emitting laser including an active layer, multiple reflectors facing each other with the active layer therebetween, a multi-quantum well structure including multiple semiconductor layers in an optical path of a laser beam emitted from the active layer and the multiple reflectors, a first electrode pair connected to a first power supply and configured to inject a current into the active layer; and a second electrode pair connected to a second power supply and configured to apply an electric field to the multi-quantum well structure in a direction perpendicular to a well surface of the multiple-quantum well structure, the method comprising:
not oscillating a laser beam during an electric-field application period; and
oscillating a laser beam during an electric-field decrease period,
wherein:
the electric-field application period is a period in which the second power supply applies the electric field to the multiple-quantum well structure,
the electric-field decrease period is a period after the electric-field application period, in which the electric field applied to the multi-quantum well structure is larger than the electric field applied during the electric-field application period, and
at least part of a current injection period is included in at least part of the electric-field application period, where the current injection period is a period in which the first power supply injects the current into the active layer, and
a current decrease period is a period after the current injection period, in which the current injected into the active layer is lower than the current injected during the current injection period.
